(19) United States
(12) Patent Application Publication
(10) Pub. No.: US 2024/0203840 A1
(43) Pub. Date: Jun. 20, 2024

(54) LEAD FRAME AND PACKAGE METHOD

(71) Applicant: Richtek Technology Corporation, Zhubei City (TW)

(72) Inventors: Shih-Chieh Lin, Hsinchu (TW); Min-Shun Lo, Miaoli (TW); Heng-Chi Huang, Hsinchu (TW); Yong-Zhong Hu, Hsinchu (TW)

(21) Appl. No.: 18/520,789

(22) Filed: Nov. 28, 2023

(30) Foreign Application Priority Data
Dec. 19, 2022 (TW) 111148727

(51) Int. Cl. H01L 23/495

(52) U.S. Cl. CPC H01L 23/49544

(57) ABSTRACT

A lead frame includes: a die pad having a die disposing area; a plurality of lead pads located around the die pad; an outer frame, located at a periphery of the die pad and the lead pads; and at least two tie bars, respectively connected between the outer frame and two opposite sides of the die pad. At least one of the die pad and the tie bars includes a thermal deformation mitigation structure.

### CROSS REFERENCE

The present invention claims priority to TW 111148727 filed on Dec. 19, 2022.

### BACKGROUND OF THE INVENTION

### Field of Invention

The present invention relates to a lead frame, especially to a lead frame capable of reducing thermal deformation, by a thermal deformation mitigation structure in at least one of a die pad and tie bars connected to the die pad.

### Description of Related Art

When the lead frame accommodates a chip die with many lead pads, more space is needed. Please refer to the prior art of U.S. Pat. No. 5,723,899 as shown in FIG. 1, wherein a lead frame 10 with a die pad 12 therein is supported by four tie bars 18. Such structure has good stability and flatness, so that it is less vulnerable to sagging or tilting due to temperature variation. However, the four tie bars 18 occupy a large space, limiting the available space for disposing the lead pads. In certain prior arts, the number of the tie bars is reduced; for example, please refer to the prior art of U.S. Pat. No. 8,093,707 as shown in FIG. 2, wherein there are only two tie bars 28 to support the lead frame 20 with the die pad 22. In such structure, to three, the stability and flatness are barely maintained, but can be easily deformed such as due to temperature variation.

To solve the aforementioned problem, a lead frame structure that is not easily thermally deformed, and that can provide enough space for disposing the lead pads, is desired.

### SUMMARY OF THE INVENTION

To solve the aforementioned problem, in one perspective, the present invention provides a lead frame, which includes: a die pad having a die disposing area; a plurality of lead pads located around the die pad; an outer frame, located at a periphery of the die pad and the lead pads; at least two tie bars, respectively connected between the outer frame and two opposite sides of the die pad; wherein at least one of the die pad and the tie bars includes a thermal deformation mitigation structure.

In one embodiment, the thermal deformation mitigation structure includes a multi-thickness structure in the die pad and the tie bars.

In one embodiment, the multi-thickness structure is disposed at fringes of the die pad and the tie bars, and the multi-thickness structure has a first thickness and a second thickness, wherein the second thickness is thicker than the first thickness, and wherein a part of the first thickness is at outer portions of the fringes of the die pad and the tie bars, and a part of the second thickness is at inner portions of the fringes of the die pad and the tie bars.

In one embodiment, a part of the first thickness in the tie bars is connected to the die pad by a larger contact area than another part of the first thickness in the tie bars which is connected to the outer frame.

In one embodiment, the first thickness is formed by semi-etching an original thickness to reduce the original thickness to the first thickness.

In one embodiment, a part of the second thickness in the tie bars includes a first width and a second width, wherein the first width is smaller than the second width, and wherein the first width is closer to the die pad, and the second width is closer to the outer frame.

In one embodiment, a part of the second thickness in the tie bars includes a continuously-varying-width structure or a discrete-step structure, wherein a narrower side of the continuously-varying-width structure or the discrete-step structure is closer to the die pad, and a wider side of the continuously-varying-width structure or the discrete-step structure is closer to the outer frame. When a chip die is disposed on the die pad, or the chip die and the lead pads are connected by lead wires, a press tool can be put on the outer frame to reduce the influence of the thermal deformation.

In one embodiment, the lead frame of the present invention can be applied to a quad flat no lead (QFN) package, quad flat package (QFP), dual in-line package (DIP), small outline package (SOP), small outline transistor (SOT) package, or system on integrated chip (SOIC) package.

In one embodiment, the tie bars are respectively connected to two eccentric positions of the die pad.

In one perspective, the present invention provides a package method, which includes: providing a lead frame, which includes a die pad, a plurality of lead pads, an outer frame, and at least two tie bars separately connected between the die pad and the outer frame, wherein at least one of the die pad and the tie bars includes a thermal deformation mitigation structure; putting a pressing tool on the outer frame; and disposing a chip die on the die pad, and/or disposing a plurality of lead wires on the corresponding lead pads. The thermal deformation mitigation structure includes a multi-thickness structure in at least one of the die pad and the tie bars.

In one embodiment, the package method further includes: removing the pressing tool; and packaging the lead frame, the chip die, and the lead wires by a package material.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a prior lead frame.

FIG. 2 shows another prior art lead frame.

FIGS. 3A-3C show schematic diagrams in different views of a lead frame according to one embodiment of the present invention.

FIG. 4 shows a schematic diagram of a lead frame according to one embodiment of the present invention.

FIG. 5 shows a schematic diagram of a lead frame according to one embodiment of the present invention.

FIG. 6 shows a schematic diagram of a lead frame according to one embodiment of the present invention.

FIG. 7 shows a schematic diagram of a lead frame according to one embodiment of the present invention.

FIG. 8 shows a schematic diagram of a lead frame according to one embodiment of the present invention.

FIG. 9 shows a flow chart of a package method according to one embodiment of the present invention.

FIG. 10 shows a flow chart of a package method according to one embodiment of the present invention.

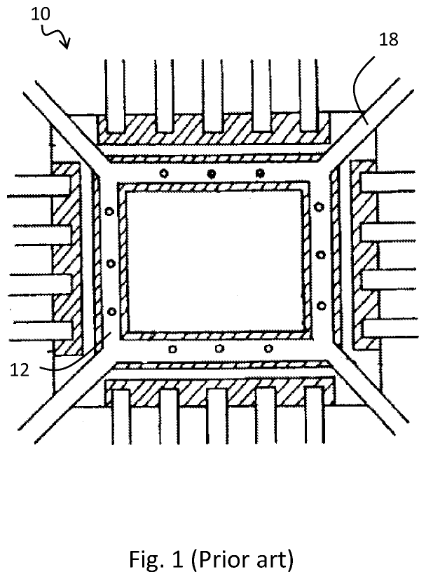

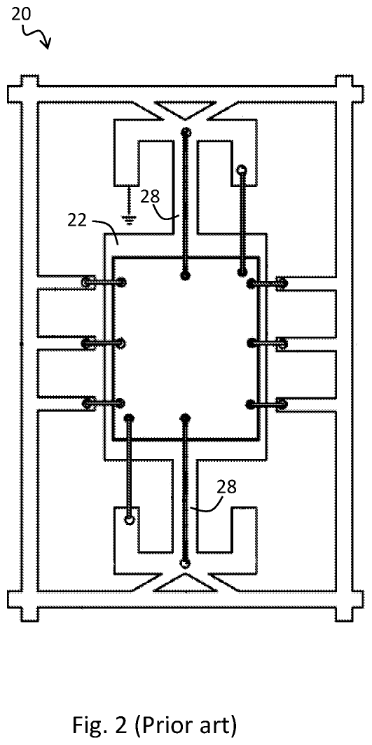

### DESCRIPTION OF THE PREFERRED EMBODIMENTS

The drawings as referred to throughout the description of the present invention are for illustration only, to show the interrelations between the components or units, but not drawn according to actual scale of sizes.

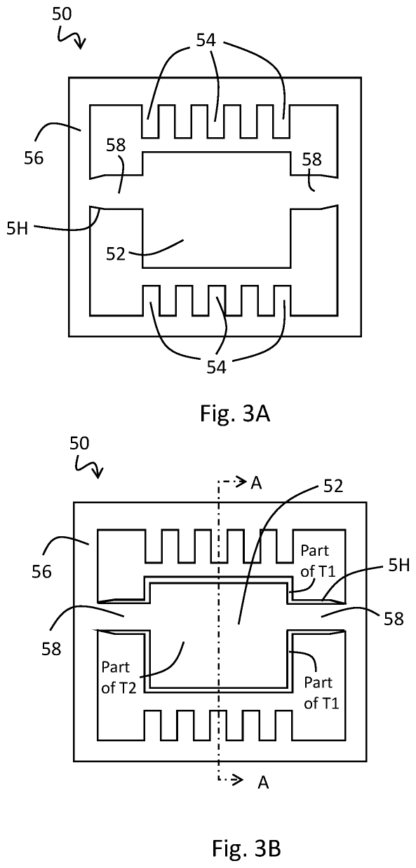

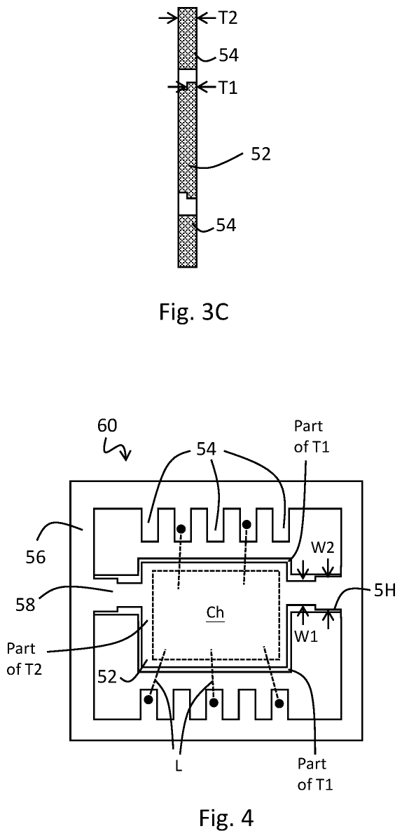

As shown in FIGS. 3A and 3B, in one perspective, the present invention provides a lead frame 50, wherein FIG. 3B shows a back view of the lead frame 50 of FIG. 3A. The lead frame 50 includes: a die pad 52 for a chip die Ch (not shown in FIG. 3A; please refer to FIG. 4) to be disposed thereon; a plurality of lead pads 54, located around the die pad 52; an outer frame 56, located at an outer periphery of the die pad 52 and the lead pads 54; and at least two tie bars 58, respectively connected between the outer frame 56 and two opposite sides of the die pad 52. At least one of the die pad 52 and the tie bars 58 includes a thermal deformation mitigation structure 5H therein. FIG. 3B shows one embodiment of the thermal deformation mitigation structure 5H, which includes a multi-thickness structure (details thereof will be explained with reference to later embodiments). One characteristic of the thermal deformation mitigation structure 5H is that the thermal deformation mitigation structure 5H has a function of isolating thermal deformation, such that the thermal deformation is restricted within local areas of the lead frame 50. In the prior art, the severe thermal deformation is mostly caused by accumulated thermal deformation of various parts in the prior lead frame. The multi-thickness structure of the thermal deformation mitigation structure 5H of the present invention can greatly reduce the influence from any local thermal deformation on the total structure of the lead frame.

Many materials used in the packaging process can be deformed due to temperature variation, to affect the stability of the subsequent processes (such as mounting the chip die and bonding the lead wires, etc.); the die pad and the tie bars in the lead frame may suffer severe deformation because of temperature variation. According to the present invention, a thermal deformation mitigation structure is provided in the die pad and/or the tie bars, to reduce the influence of the thermal deformation on the total structure of the lead frame.

Note that the die pads, the lead pads, the outer frames, the tie bars, and the thermal deformation mitigation structures in the lead frames shown in the drawings are for illustrative purpose, but not to limit the broadest scope of the present invention. The sizes, scales or configurations of the die pads, the lead pads, the outer frames, the tie bars, and the thermal deformation mitigation structures can be modified by one skilled in this art under the teaching by the present invention.

Please refer to FIGS. 3B, 3C and 4 (wherein FIG. 3C shows a cross-section view according to a cross-section line AA in FIG. 3B), in one embodiment, the thermal deformation mitigation structure 5H includes a multi-thickness structure (for example, including thicknesses T1 and T2 in FIG. 3C, wherein T2>T1) which is provided in at least one of the die pad 52 and the tie bars 58. The multi-thickness structure of the present invention can have one same width or have multiple widths. For example, a part of the second thickness T2 of the multi-thickness structure in the tie bars 58 can include a multi-width structure (the multi-width structure can be a continuously-varying-width structure or a discrete-step structure, which will be explained in detail later).

In one embodiment, the multi-thickness structure is disposed at fringes of the die pad 52 and the tie bars 58. The multi-thickness structure has a first thickness T1 and a second thickness T2 which is thicker than the first thickness. A part of the first thickness T1 is at the outer portions of the fringes of the die pad 52 and the tie bars 58, and a part of the second thickness T2 is at the inner portions of the fringes of the die pad 52 and the tie bars 58.

According to the present invention, in different embodiments, the thickness of the multi-thickness structure can be arranged in various ways. For example, in one embodiment, the first thickness T1 can be one half of the second thickness T2. Or, in other embodiments, there can be other ratios between the first thickness T1 and the second thickness T2; for example, the first thickness T1 can be one third or two thirds of the second thickness T2. In one embodiment, referring to FIG. 4, the part of the second thickness T2 in the tie bars 58 can include a discrete-step structure having widths W1 and W2 (FIG. 4), or in another embodiment, referring to FIG. 5, the part of the second thickness T2 in the tie bars 58 can include a continuously-varying-width structure (in FIG. 5, the width of the second thickness T2 is continuously varying along the length direction (i.e., the horizontal direction in FIG. 5), with a wider side WW and a narrower side WN). Different thickness and width combinations can be designed according to application needs. In the example shown in FIGS. 3A and 3B, the width of the part of the second thickness T2 becomes gradually narrower in a direction from the die pad 52 the outer frame 56.

In one embodiment, the first thickness T1 is one half of the second thickness T2 (as shown in FIGS. 3B and 3C). In one embodiment, the first thickness T1 can be formed by a semi-etching process to reduce an original thickness to the first thickness. The free edges of the parts of the first thickness T1 and the second thickness T2 can be formed by through etching to fully disconnect these free edges from other structures.

As shown in FIG. 3B, in one embodiment, a part of the first thickness T1 in the tie bars 58 is connected to the die pad 52 by a larger contact area than another part of the first thickness T1 in the tie bars which is connected to the outer frame 56.

In FIG. 4, the part of the second thickness T2 in the tie bars 58 includes a first width W1 and a second width W2, wherein the first width W1 is smaller than the second width W2. The first width W1 is closer to the die pad 52, and the second width T2 is closer to the outer frame 56.

In comparison with the discrete-step structure of the part of the second thickness T2 in the tie bars 58 as shown in FIG. 4, FIG. 5 shows a continuously-varying-width structure included in the part of the of the second thickness T2 in the tie bars 58. The wider side WW of the continuously-varying-width structure is closer to the outer frame 56, and the narrower side WN of the continuously-varying-width structure is closer to the die pad 52. In brief, the wider side of the continuously-varying-width structure or the discrete-step structure in the multi-width structure, is closer to the outer frame 56; the narrower the side of the continuously-varying-width structure or structure with discrete-step structure in the multi-width structure, is closer to the die pad 52.

In one embodiment, the thermal deformation mitigation structure in the tie bars 58 can further include a through hole (not shown), to further release the thermal deformation by breaking the accumulation of the thermal deformation of different sides of the lead frame.

Referring to the embodiment as shown in FIG. 4, in the lead frame 60, when the chip die Ch is disposed on the die pad 52, or the chip die Ch and the lead pads 54 are connected by lead wires L, a press tool can be put on the outer frame 56 (or on the outer frame 56 and the tie bars 58) to fix the lead frame 60 and to avoid vibration. Note that the embodiment and the drawings of the present invention are described by using a single chip die package as an example; however, the present invention also can be applied to an lead frame with an array of chip dies, with proper modifications.

In one embodiment, the lead frame of the present invention can be applied to a quad flat no lead (QFN) package, quad flat package (QFP), dual in-line package (DIP), small outline package (SOP), small outline transistor (SOT) package, or system on integrated chip (SOIC) package. The aforementioned package types are examples that the present invention can be applied to; besides the above, the present invention can also be applied to other types of package structures.

Please refer to FIGS. 3A, 4, and 5; in one embodiment, the tie bars 58 are respectively connected to two eccentric positions of the die pad 52. In the lead frame 70 as shown in FIG. 5, the tie bars 58 at the two sides of the die pad 52 are not aligned with a horizontal center line HC of the die pad 52 (or in another perspective, the centers of the tie bars 58 are not aligned with the horizontal center line HC of the die pad 52). As such, the thermal deformation transmitted via the tie bars 58 can merely affect a small part of the die pad 52.

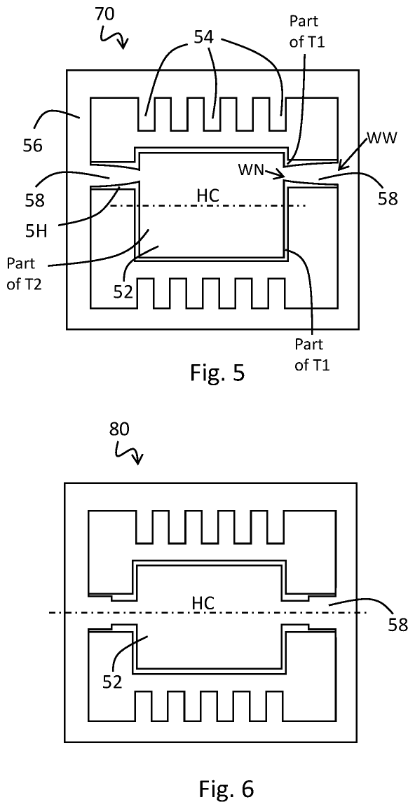

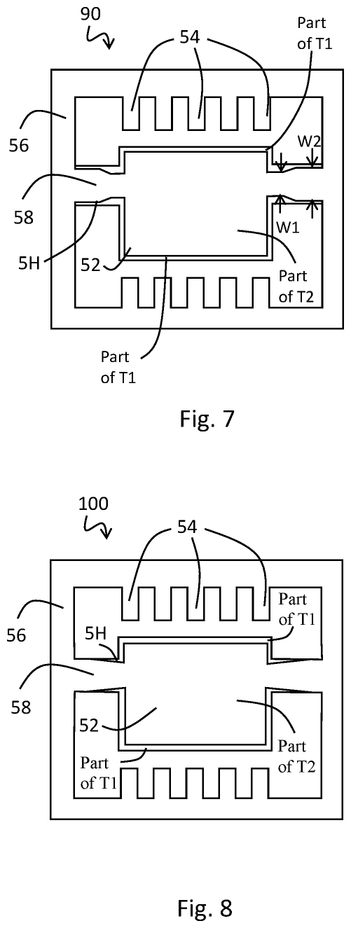

In the lead frame 80 as shown in FIG. 6, the tie bars 58 are connected to a center portion of the die pad 52 with respect to a vertical direction in FIG. 6, that is, in the lead frame 80 as shown in FIG. 6, the tie bars 58 on both sides of the die pad 52 overlay the horizontal center line HC of the die pad 52. The previous and this embodiments show that the tie bars can be connected to center or eccentric positions of the die pad 52.

The lead frame 90 as shown in FIG. 8 shows one embodiment of the tie bar 58 which includes a thermal deformation mitigation structure 5H having a multi-width structure. The part of the second thickness T2 in the tie bars 58 includes two sections respectively having different constant widths W1 and W2, and a continuously-varying-width section (having bevel edges) connecting the widths W1 and W2; this is an embodiment wherein the part of the second thickness T2 has a combination of constant and continuously-varying widths.

The lead frame 100 as shown in FIG. 8 shows one embodiment of the tie bar 58 which includes a thermal deformation mitigation structure 5H having a multi-thickness structure. In this embodiment, a part of the first thickness T1 in the tie bars 58 is connected to the die pad 52 by a larger contact area than another part of the first thickness T1 in the tie bars which is connected to the outer frame 56. The width of the first thickness T1 gradually decreases from the connection between the tie bars 58 and the die pad 52 to the connection between the tie bars 58 and the outer frame 56.

According to the data obtained by the inventors, the lead frame provided by the present invention can reduce thermal deformation at least by 20%, and in better case by as high as 30% (measured by the maximum vertical thermal deformation in the lead frame, at a temperature between 220° C. and 230° C.), in comparison with the prior art. Thus, the present invention has a very obvious improved effect.

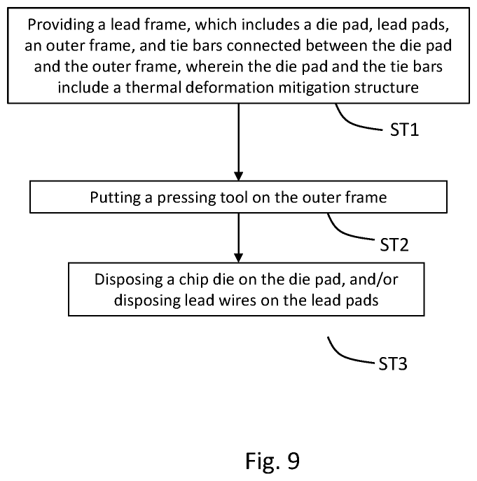

Please refer to FIG. 9. In one perspective, the present invention provides a package method, which includes: providing a lead frame, which includes a die pad, a plurality of lead pads, an outer frame, and at least two tie bars separately connected between the die pad and the outer frame, wherein at least one of the die pad and the tie bars includes a thermal deformation mitigation structure (ST1); putting a pressing tool on the outer frame (ST2); and disposing a chip die on the die pad, and/or disposing a plurality of lead wires on the lead pads (ST3). The thermal deformation mitigation structure includes a multi-thickness structure, in at least one of the die pad and the tie bars. The details of the die pad, the lead pads, the outer frame, the tie bars, and the thermal deformation mitigation structure have been described in the aforementioned embodiments.

As illustrated by the above-mentioned embodiments, the number of the tie bars required by the present invention is less than the prior art, while the lead frame of the present invention can have less thermal deformation and more space for accommodating the lead pads. Besides, the packaging steps required by the present invention are not more difficult than the prior art. Hence, the improvement by the present invention is very significant.

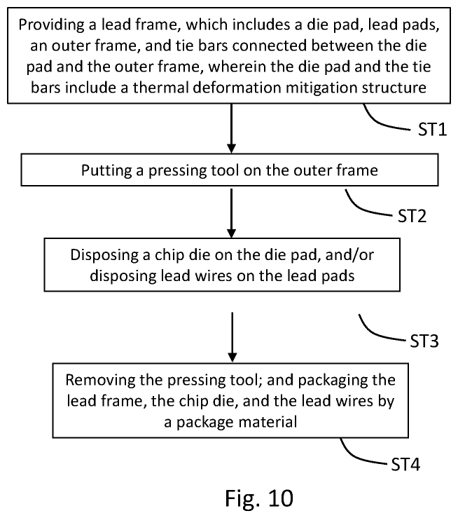

Please refer to FIG. 10, in one embodiment, the package method further includes: removing the pressing tool, and packaging the lead frame, the chip die, and the lead wires by a package material (ST4). The package material for example is the package material that is used to package the lead frame.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. Various modifications can be made under the spirit of the present invention. For example, the number of the chip dies can be different from what is shown in drawings; the components can be arranged in different configurations; the shapes of the components can be different, etc. Those skilled in this art can readily conceive variations and modifications within the spirit of the present invention, which should all be regarded as falling in the scope of the present invention.

What is claimed is:

1. A lead frame, including:
a die pad having a die disposing area;
a plurality of lead pads located around the die pad;
an outer frame, located at a periphery of the die pad and the lead pads;
at least two tie bars, respectively connected between the outer frame and two opposite sides of the die pad;
wherein at least one of the die pad and the tie bars includes a thermal deformation mitigation structure.

2. The lead frame according to claim 1, wherein the thermal deformation mitigation structure includes a multi-thickness structure in the die pad and the tie bars.

3. The lead frame according to claim 2, wherein the multi-thickness structure is disposed at fringes of the die pad and the tie bars, and the multi-thickness structure has a first thickness and a second thickness, wherein the second thickness is thicker than the first thickness, wherein a part of the first thickness is at outer portions of the fringes of the die pad and the tie bars, and a part of the second thickness is at inner portions of the fringes of the die pad and the tie bars.

4. The lead frame according to claim 3, wherein a part of the first thickness in the tie bars is connected to the die pad by a larger contact area than another part of the first thickness in the tie bars which is connected to the outer frame.

5. The lead frame according to claim 3, wherein the first thickness is formed by semi-etching an original thickness to reduce the original thickness to the first thickness.

6. The lead frame according to claim 3, wherein a part of the second thickness in the tie bars includes a first width and a second width, wherein the first width is smaller than the second width, and wherein the first width is closer to the die pad, and the second width is closer to the outer frame.

7. The lead frame according to claim 3, wherein a part of the second thickness in the tie bars includes a continuously-varying-width structure or a discrete-step structure, wherein a narrower side of the continuously-varying-width structure or the discrete-step structure is closer to the die pad, and a wider side of the continuously-varying-width structure or the discrete-step structure is closer to the outer frame.

8. The lead frame according to claim 1, wherein the lead frame is applied to a quad flat no lead (QFN) package, quad flat package (QFP), dual in-line package (DIP), small outline package (SOP), small outline transistor (SOT) package, or system on integrated chip (SOIC) package.

9. The lead frame according to claim 1, wherein when a chip die is disposed on the die pad, or when the chip die and the lead pads are connected by lead wires, a press tool is put on the outer frame to reduce the influence of thermal deformation.

10. The lead frame according to claim 1, wherein the tie bars are respectively connected to two eccentric positions of the die pad.

11. A package method, comprising:
providing a lead frame, which includes a die pad, a plurality of lead pads, an outer frame, and at least two tie bars separately connected between the die pad and the outer frame, wherein at least one of the die pad and the tie bars includes a thermal deformation mitigation structure;
putting a pressing tool on the outer frame; and
disposing a chip die on the die pad, and/or disposing a plurality of lead wires on the corresponding lead pads;
wherein the thermal deformation mitigation structure includes a multi-thickness structure in at least one of the die pad and the tie bars.

12. The package method according to claim 11, further including: removing the pressing tool; and packaging the lead frame, the chip die, and the lead wires by a package material.
